(19) United States
(12) Patent Application Publication
(10) Pub. No.: US 2013/0112466 A1
(43) Pub. Date: May 9, 2013

(54) ELECTRONIC COMPONENT AND METHOD FOR MANUFACTURING THE SAME

(71) Applicant: Murata Manufacturing Co., Ltd., Nagaokakyo-shi (JP)

(72) Inventor: Takahiro MORI, Nagaokakyo-shi (JP)

(73) Assignee: MURATA MANUFACTURING CO., LTD., Nagaokakyo-shi (JP)

(21) Appl. No.: 13/726,757

(22) Filed: Dec. 26, 2012

Related U.S. Application Data
(63) Continuation of application No. PCT/JP2011/060958, filed on May 12, 2011.

(30) Foreign Application Priority Data
Jul. 6, 2010 (JP) 2010-153992

(51) Int. Cl. H05K 3/30; H05K 1/11

(52) U.S. Cl. CPC H05K 3/305; H05K 1/115
USPC 174/260; 427/58

(57) ABSTRACT

An electronic component in which a direction identification mark can be easily formed includes a laminate including a plurality of laminated insulating material layers and a mounting surface parallel or substantially parallel to a z-axis direction. A directional coupler including a main line and a sub-line is included in the laminate. A direction identification mark is provided on an upper surface of the laminate which is parallel or substantially parallel to the mounting surface, and is defined by a via-hole conductor portion, which is obtained by filling a via hole provided in the insulating material layers with a conductor, being exposed from the upper surface.

### BACKGROUND OF THE INVENTION

1. Field of the Invention

The present invention relates to an electronic component and a method for manufacturing the same, and more specifically, to an electronic component including a mounting surface parallel or substantially parallel to a lamination direction and a method for manufacturing the same.

2. Description of the Related Art

As an existing electronic component, for example, a known directional coupler is disclosed in Japanese Unexamined Patent Application Publication No. 2006-191221. In the directional coupler disclosed in Japanese Unexamined Patent Application Publication No. 2006-191221, a laminate including laminated dielectric layers is formed. External electrodes are provided on side surfaces of the laminate located on both ends in a lamination direction thereof. When the directional coupler as described above is mounted on a circuit board, a surface of the laminate parallel to the lamination direction is used as a mounting surface. In other words, the directional coupler is mounted on the circuit board such that the surface of the laminate parallel to the lamination direction faces the circuit board.

Meanwhile, with regard to the directional coupler disclosed in Japanese Unexamined Patent Application Publication No. 2006-191221, it is necessary to mount the directional coupler on the circuit board while identifying the direction of the directional coupler. As a method for identifying the direction of the directional coupler, a direction identification mark is generally provided on a surface (hereinafter, referred to as an upper surface) of the laminate which is opposed to the mounting surface. Then, the direction identification mark is formed by applying a conductive paste or the like to the upper surface of the laminate by screen printing. However, the upper surface of the laminate is defined by a row of side surfaces of dielectric layers, not a principal surface of a dielectric layer. Thus, small recesses and projections are formed on the upper surface of the laminate. Therefore, it is difficult to form a direction identification mark on such an upper surface of the laminate by screen printing.

### SUMMARY OF THE INVENTION

To overcome the problems described above, preferred embodiments of the present invention provide an electronic component in which a direction identification mark can be easily and effectively provided and a method for manufacturing the same.

An electronic component according to a preferred embodiment of the present invention includes a laminate including a plurality of laminated insulating material layers and a mounting surface parallel or substantially parallel to a lamination direction, a circuit element provided in the laminate, and a direction identification mark defined by a via hole filled portion, which is obtained by filling a via hole provided in the insulating material layers with a material different from that of the insulating material layers, being exposed from an upper surface of the laminate which is parallel or substantially parallel to the mounting surface.

A method for manufacturing the electronic component according to a preferred embodiment of the present invention includes a first step of preparing a mother laminate in which a via hole is filled with a material different from that of the insulating material layers to provide a via hole filled region, and a second step of cutting the mother laminate to obtain the laminate. In the second step, the via hole filled region is divided to produce the via hole filled portion.

According to various preferred embodiments of the present invention, the direction identification mark can be easily and effectively provided.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a perspective view of an electronic component according to a preferred embodiment of the present invention.

FIG. 2 is an exploded perspective view of the electronic component according to a preferred embodiment of the present invention.

FIG. 3 is a diagram schematically illustrating the electronic component according to a preferred embodiment of the present invention.

FIG. 4 is an external perspective view of a mother laminate produced during manufacturing of the electronic component.

FIG. 5 is an external perspective view of an electronic component according to a modification of a preferred embodiment of the present invention.

FIG. 6 is an exploded perspective view of an electronic component according to a first modification of a preferred embodiment of the present invention.

FIG. 7 is a diagram schematically illustrating the electronic component according to the first modification of a preferred embodiment of the present invention.

FIG. 8 is an exploded perspective view of an electronic component according to a second modification of a preferred embodiment of the present invention.

FIG. 9 is a diagram schematically illustrating the electronic component according to the second modification of a preferred embodiment of the present invention.

### DETAILED DESCRIPTION OF THE PREFERRED EMBODIMENTS

Hereinafter, an electronic component according to preferred embodiments of the present invention and a method for manufacturing the same will be described.

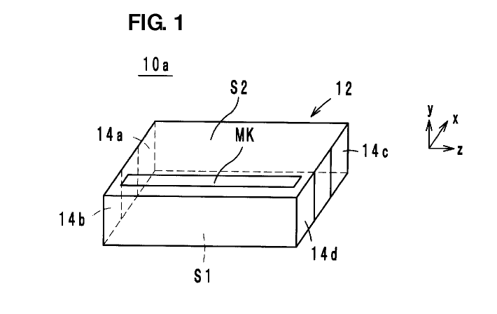

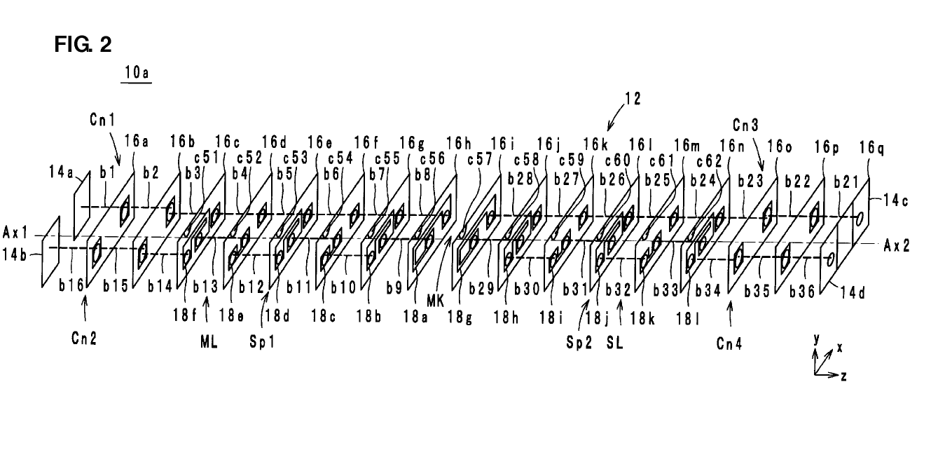

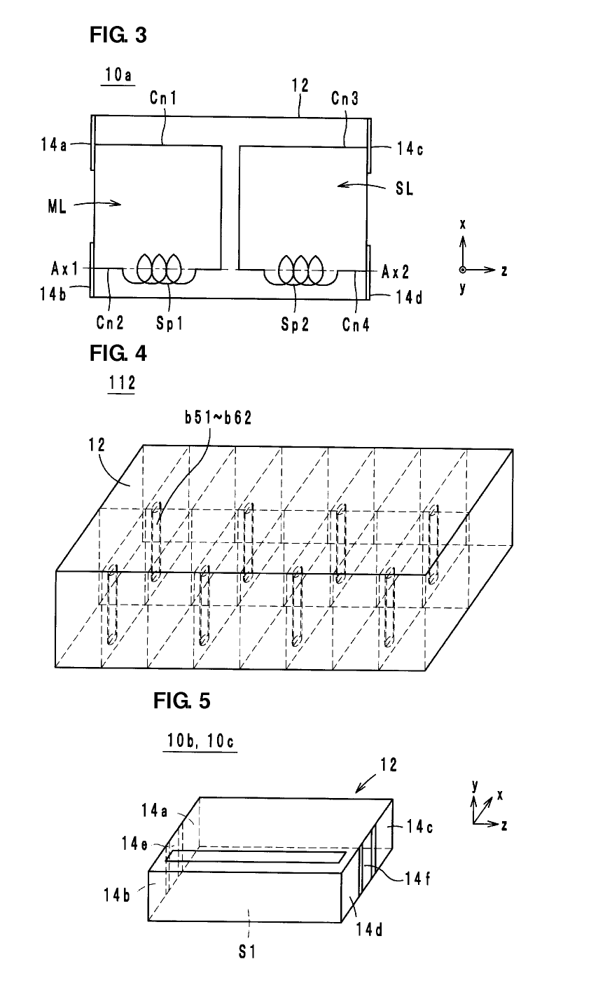

Hereinafter, the electronic component according to a preferred embodiment of the present invention will be described with reference to the drawings. FIG. 1 is a perspective view of the electronic component 10a according to the present preferred embodiment. FIG. 2 is an exploded perspective view of the electronic component 10a according to the present preferred embodiment. FIG. 3 is a diagram schematically illustrating the electronic component 10a according to the present preferred embodiment. Hereinafter, a lamination direction of the electronic component 10a is defined as a z-axis direction. When the electronic component 10a is seen in a plan view from the z-axis direction, a direction along the long sides of the electronic component 10a is defined as an x-axis direction, and a direction along the short sides of the electronic component 10a is defined as a y-axis direction. The x-axis, the y-axis, and the z-axis are orthogonal to each other.

As shown in FIGS. 1 and 2, the electronic component 10a includes a laminate 12, external electrodes 14 (14a to 14d), a main line ML, a sub-line SL, and a direction identification mark MK.

As shown in FIG. 1, the laminate 12 preferably has a rectangular or substantially rectangular parallelepiped shape, and includes the main line ML and the sub-line SL therein. The laminate 12 includes a mounting surface S1 parallel or substantially parallel to the z-axis direction. More specifically, the mounting surface S1 is a lower surface of the laminate 12 on the negative direction side in the y-axis direction. In addition, the laminate 12 includes an upper surface S2 parallel or substantially parallel to the mounting surface S1. The upper surface S2 is a surface of the laminate 12 on the positive direction side in the y-axis direction.

As shown in FIG. 2, the laminate 12 includes insulating material layers 16 (16a to 16q) that are laminated in order from the negative direction side to the positive direction side in the z-axis direction. Each insulating material layer 16 preferably has a rectangular or substantially rectangular shape, and is made of a dielectric material. Hereinafter, a surface of each insulating material layer 16 on the positive direction side in the z-axis direction is referred to as a front surface, and a surface of each insulating material layer 16 on the negative direction side in the z-axis direction is referred to a back surface.

As shown in FIG. 2, each of the external electrodes 14a and 14b is provided on a side surface of the laminate 12 on the negative direction side in the z-axis direction. In other words, each of the external electrodes 14a and 14b is provided on the back surface of the insulating material layer 16a. In addition, the external electrode 14a is located on the positive direction side of the external electrode 14b in the x-axis direction. The external electrodes 14a and 14b are provided only on the side surface of the laminate 12 on the negative direction side in the z-axis direction and are not provided on any other surfaces of the laminate 12.

Furthermore, as shown in FIG. 2, each of the external electrodes 14c and 14d is provided on a side surface of the laminate 12 on the positive direction side in the z-axis direction. In other words, each of the external electrodes 14c and 14d is provided on the front surface of the insulating material layer 16q. In addition, the external electrode 14c is located on the positive direction side of the external electrode 14d in the x-axis direction. The external electrodes 14c and 14d are provided only on the side surface of the laminate 12 on the positive direction side in the z-axis direction and are not provided on any other surfaces of the laminate 12.

The main line ML is connected between the external electrodes 14a and 14b, and includes a spiral portion Sp1 and connection portions Cn1 and Cn2 as shown in FIG. 2. The spiral portion Sp1 is a signal line which has a spiral shape so as to wind spirally counterclockwise from the positive direction side towards the negative direction side in the z-axis direction when seen in a plan view from the positive direction side in the z-axis direction. In other words, the spiral portion Sp1 has a central axis Ax1 parallel or substantially parallel to the z-axis direction. The spiral portion Sp1 includes signal conductors 18a to 18f and via-hole conductors b9 to b13.

Each of the signal conductors 18a to 18f is preferably made of a conductive material and produced by bending a linear conductor. Hereinafter, when each the signal conductor 18 is seen in a plan view from the positive direction side in the z-axis direction, an end of each signal conductor 18 on the upstream side in the counterclockwise direction is referred to as an upstream end, and an end of each signal conductor 18 on the downstream side in the counterclockwise direction is referred to as a downstream end.

The via-hole conductors b9 to b13 extend through the insulating material layers 16h, 16g, 16f, 16e, and 16d, respectively, in the z-axis direction and connect the signal conductors 18. More specifically, the via-hole conductor b9 connects the downstream end of the signal conductor 18a to the upstream end of the signal conductor 18b. The via-hole conductor b10 connects the downstream end of the signal conductor 18b to the upstream end of the signal conductor 18c. The via-hole conductor b11 connects the downstream end of the signal conductor 18c to the upstream end of the signal conductor 18d. The via-hole conductor b12 connects the downstream end of the signal conductor 18d to the upstream end of the signal conductor 18e. The via-hole conductor b13 connects the downstream end of the signal conductor 18e to the upstream end of the signal conductor 18f.

As shown in FIG. 2, the connection portion Cn1 connects an end of the spiral portion Sp1 on the positive direction side in the z-axis direction (i.e., the upstream end of the signal conductor 18a) to the external electrode 14a, and is includes via-hole conductors b1 to b8. The via-hole conductors b1 to b8 extend through the insulating material layers 16a to 16h, respectively, in the z-axis direction, and are connected to each other so as to define a single via-hole conductor.

As shown in FIG. 2, the connection portion Cn2 connects an end of the spiral portion Sp1 on the negative direction side in the z-axis direction (i.e., the downstream end of the signal conductor 18f) to the external electrode 14b, and includes via-hole conductors b14 to b16. The via-hole conductors b14 to b16 extend through the insulating material layers 16c, 16b, and 16a, respectively, in the z-axis direction, and are connected to each other, thereby defining a single via-hole conductor. As described above, the main line ML is connected between the external electrodes 14a and 14b as shown in FIG. 3.

The sub-line SL is connected between the external electrodes 14c and 14d, and is electromagnetically coupled to the main line ML so as to define a directional coupler (circuit element). As shown in FIG. 2, the sub-line SL includes a spiral portion Sp2 and connection portions Cn3 and Cn4.

The spiral portion Sp2 is a signal line which has a spiral shape so as to extend spirally clockwise from the negative direction side towards the positive direction side in the z-axis direction when being seen in a plan view from the positive direction side in the z-axis direction. In other words, the spiral portion Sp2 has a central axis Ax2 parallel or substantially parallel to the z-axis direction. As shown in FIG. 3, the central axis Ax2 coincides or substantially coincides with the central axis Ax1. The spiral portion Sp2 includes signal conductors 18g to 181 and via-hole conductors b29 to b33.

Each of the signal conductors 18g to 181 is preferably made of a conductive material and produced by bending a linear conductor. Hereinafter, when each signal conductor 18 is seen in a plan view from the positive direction side in the z-axis direction, an end of each signal conductor 18 on the upstream side in the clockwise direction is referred to as an upstream end, and an end of each signal conductor 18 on the downstream side in the clockwise direction is referred to as a downstream end.

The via-hole conductors b29 to b33 extend through the insulating material layers 16i to 16m, respectively, in the z-axis direction, and connect the signal conductors 18. More specifically, the via-hole conductor b29 connects the upstream end of the signal conductor 18g to the downstream end of the signal conductor 18h. The via-hole conductor b30 connects the upstream end of the signal conductor 18h to the downstream end of the signal conductor 18i. The via-hole conductor b31 connects the upstream end of the signal conductor 18i to the downstream end of the signal conductor 18j. The via-hole conductor b32 connects the upstream end of the signal conductor 18j to the downstream end of the signal conductor 18k. The via-hole conductor b33 connects the upstream end of the signal conductor 18k to the downstream end of the signal conductor 181.

As shown in FIG. 2, the connection portion Cn3 connects an end of the spiral portion Sp2 on the negative direction side in the z-axis direction (i.e., the downstream end of the signal conductor 18g) to the external electrode 14c, and includes via-hole conductors b21 to b28. The via-hole conductors b21 to b28 extend through the insulating material layer 16q, 16p, 16o, 16n, 16m, 161, 16k, and 16j, respectively, in the z-axis direction, and are connected to each other so as to define a single via-hole conductor.

As shown in FIG. 2, the connection portion Cn4 connects an end of the spiral portion Sp2 on the positive direction side in the z-axis direction (i.e., the upstream end of the signal conductor 181) to the external electrode 14d, and includes via-hole conductors b34 to b36. The via-hole conductors b34 to b36 extend through the insulating material layers 16o to 16q, respectively, in the z-axis direction, and are connected to each other so as to define a single via-hole conductor. As described above, the sub-line SL is connected between the external electrodes 14c and 14d as shown in FIG. 3.

The direction identification mark MK is provided on the upper surface S2 of the laminate 12. More specifically, via-hole conductor portions c51 to c62 each obtained by dividing a via-hole conductor into halves are provided in the laminate 12. The via-hole conductor portions c51 to c62 are preferably formed by filling semicircular via holes, which extend through the insulating material layers 16c to 16n in the z-axis direction, with the same conductor as the conductor defining the main line ML and the sub-line SL. Then, the via-hole conductor portions c51 to c62 extend through the insulating material layers 16c to 16n, respectively, in the z-axis direction, and are connected to each other so as to define a single bar-shaped conductor portion.

Furthermore, each of the via-hole conductor portions c51 to c62 preferably has a semicircular shape when seen in a plan view from the z-axis direction, and is in contact at their chord portions with long sides of the insulating material layers 16c to 16n, respectively, on the positive direction side in the y-axis direction. Thus, the via-hole conductor portions c51 to c62 are exposed from the upper surface S2 of the laminate 12. In addition, the direction identification mark MK is defined by the portions of the via-hole conductor portions c51 to c62 which are exposed from the upper surface S2 of the laminate 12.

Here, the direction identification mark MK is not configured to have point symmetry about the center (the intersection between the diagonal lines) of the upper surface S2 of the laminate 12. In the present preferred embodiment, the direction identification mark MK preferably extends in the z-axis direction near the long side of the upper surface S2 on the negative direction side in the x-axis direction. Thus, the direction of the electronic component 10a can be identified by using the direction identification mark MK.

In the electronic component 10a configured as described above, preferably the external electrode 14a is used as an input port, the external electrode 14b is used as a main output port, the external electrode 14c is used as a monitor output port, and the external electrode 14d is used as a 50-Ω terminal port, for example.

Next, a method for manufacturing the electronic component 10a according to a preferred embodiment of the present invention will be described with reference to FIGS. 1, 2, and 4. FIG. 4 is an external perspective view of a mother laminate 112 produced during manufacturing of the electronic component 10a.

First, ceramic green sheets that are to be the insulating material layers 16 are prepared. Next, the via-hole conductors b1 to b16, b21 to b36, and b51 to b62 are formed in the ceramic green sheets, respectively, which are to be the insulating material layers 16. The via-hole conductors b51 to b62 refer to via-hole conductors that have not been divided for the via-hole conductor portions c51 to c62. When forming the via-hole conductors b1 to b16, b21 to b36, and b51 to b62, a laser beam is applied to the ceramic green sheets, which are to be the insulating material layers 16, to form via holes. Next, the via holes are filled with a conductive paste preferably of Ag, Pd, Cu, Au, an alloy thereof, or other suitable material, for example, by a method such as a printing application, for example.

Next, a conductive paste preferably including Ag, Pd, Cu, Au, an alloy thereof, or other suitable material, for example, as a principal component is applied to the front surfaces of the ceramic green sheets that are to be the insulating material layers 16c to 16n, by a method, such as a screen printing method or a photolithographic method, for example, to form the signal conductors 18. It is noted that when the signal conductors 18 are formed, the filling of the via holes with the conductive paste may be conducted.

In addition, a conductive paste preferably including Ag, Pd, Cu, Au, an alloy thereof, or other suitable material, for example, as a principal component is applied to the back surface of the ceramic green sheet that is to be the insulating material layer 16a and to the front surface of the ceramic green sheet that is to be the insulating material layer 16q, by a method such as a screen printing method or a photolithographic method, for example, to form the external electrodes 14a to 14d.

It is noted that after the signal conductors 18 and the external electrodes 14a to 14d are formed, the via-hole conductors b1 to b16, b21 to b36, and b51 to b62 may be formed.

Next, each ceramic green sheet is laminated. Specifically, the ceramic green sheets that are to be the insulating material layers 16a to 16q are individually laminated and pressure-bonded so as to be aligned in order from the negative direction side to the positive direction side in the z-axis direction. By the above processes, the mother laminate 112 in which the via-hole conductors b51 to b62 are provided is formed as shown in FIG. 4. This mother laminate is subjected to main pressure bonding by a hydrostatic press or other suitable method, for example.

Next, the mother laminate 112 is cut with a cutting blade to obtain a laminate 12 with a predetermined dimension. At that time, the mother laminate 112 is cut along dotted lines in FIG. 4 to divide the via-hole conductors b51 to b62 into pairs of the via-hole conductor portions c51 to c62. By doing so, the via-hole conductor portions c51 to c62 are exposed from the upper surface S2 of the laminate 12. Then, the unfired laminate 12 is subjected to de-binder treatment and firing.

With the processes described above, a fired laminate 12 is obtained. The laminate 12 is subjected to barrel polishing to perform chamfering.

Finally, Ni plating/Sn plating is applied to the front surfaces of the external electrodes 14. With the processes described above, the electronic component 10a shown in FIG. 1 is completed.

In the electronic component 10a configured as described above and the method for manufacturing the electronic component 10a, the direction identification mark MK can be easily provided. More specifically, the electronic component 10a includes the mounting surface S1 parallel or substantially parallel to the z-axis direction. Thus, the direction identification mark MK is preferably provided on the upper surface S2 parallel or substantially parallel to the mounting surface S1. In an existing electronic component, it is difficult to provide the direction identification mark MK on the upper surface S2 parallel to the z-axis direction.

Meanwhile, in the electronic component 10a, the via-hole conductor portions c51 to c62 exposed from the upper surface S2 are preferably formed by forming the via-hole conductors b51 to b62 and dividing each via-hole conductor into two portions. Then, the portions of the via-hole conductor portions c51 to c62 which are exposed from the upper surface S2 are used as the direction identification mark MK. As described above, in the electronic component 10a, the direction identification mark MK is formed by the processes of forming via-hole conductors and cutting a mother laminate, which processes are generally included in the process for manufacturing the electronic component 10a. Thus, it is not necessary to add a new process in order to form the direction identification mark MK. Thus, in the electronic component 10a, the direction identification mark MK can be easily formed.

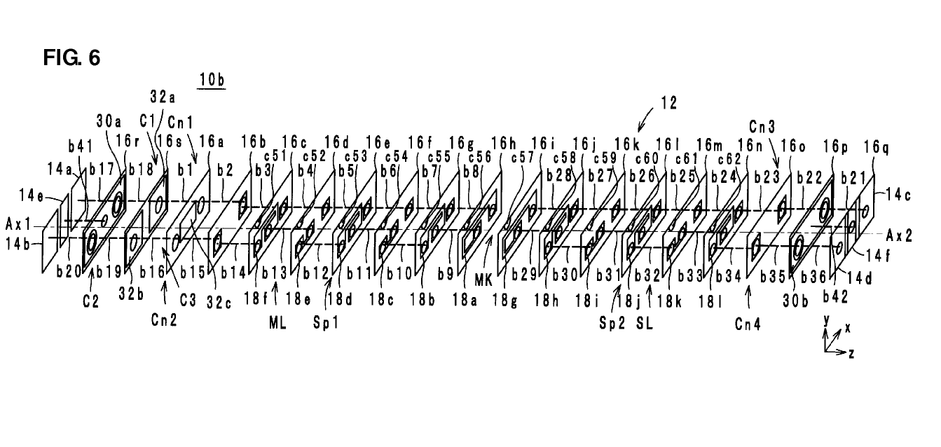

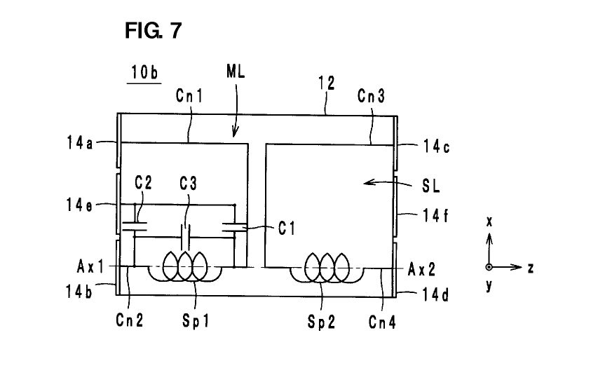

Hereinafter, an electronic component 10b according to a first modification of a preferred embodiment of the present invention will be described with reference to the drawings. FIG. 5 is an external perspective view of an electronic component 10b or 10c according to a first modification of a preferred embodiment of the present invention. FIG. 6 is an exploded perspective view of the electronic component according to the first modification. FIG. 7 is a diagram schematically illustrating the electronic component 10b according to the first modification.

In the electronic component 10a, the external electrodes 14a to 14d are provided in the laminate 12. Meanwhile, in the electronic component 10b, as shown in FIG. 5, external electrodes 14e and 14f are provided in addition to the external electrodes 14a to 14d.

Furthermore, in the electronic component 10a, only the main line ML and the sub-line SL are provided within the laminate 12. Meanwhile, in the electronic component 10b, as shown in FIGS. 6 and 7, capacitors C1 to C3 are provided within the laminate 12, in addition to the main line ML and the sub-line SL.

The external electrode 14e is preferably arranged so as to be interposed between the external electrodes 14a and 14b on the side surface on the negative direction side in the z-axis direction. Meanwhile, the external electrode 14f is provided so as to be interposed between the external electrodes 14c and 14d on the side surface on the positive direction side in the z-axis direction.

As shown in FIG. 7, the capacitor C1 is connected between the end of the spiral portion Sp1 on the positive direction side in the z-axis direction and the external electrode 14e. The capacitor C2 is connected between the end of the spiral portion Sp1 on the negative direction side in the z-axis direction and the external electrode 14e. The capacitor C3 is connected in parallel with the spiral portion Sp1 between the capacitors C1 and C2. Thus, the capacitors C1 to C3 define a π type low-pass filter.

Specifically, the capacitor C1 includes a ground conductor 30a and a capacitor conductor 32a. The ground conductor 30a is a rectangular conductor provided on the front surface of an insulating material layer 16r, and is connected to the external electrode 14e via a via-hole conductor b41. Meanwhile, the ground conductor 30a is not connected to the external electrodes 14a and 14b. In other words, the ground conductor 30a is not connected to via-hole conductors b17 and b20. The capacitor conductor 32a is preferably a rectangular or substantially rectangular conductor provided on the front surface of an insulating material layer 16s, and faces the ground conductor 30a. The capacitor conductor 32a is connected to the external electrode 14a via the via-hole conductors b17 and b18. Meanwhile, the capacitor conductor 32a is not connected to the external electrode 14e.

The capacitor C2 includes the ground conductor 30a and a capacitor conductor 32b. The capacitor conductor 32b is preferably a rectangular or substantially rectangular conductor provided on the front surface of the insulating material layer 16s, and faces the ground conductor 30a. The capacitor conductor 32b is connected to the external electrode 14b via the via-hole conductors b19 and b20. Meanwhile, the capacitor conductor 32b is not connected to the external electrode 14e.

The capacitor C3 includes the capacitor conductors 32a to 32c. The capacitor conductor 32c is preferably a rectangular or substantially rectangular conductor layer provided on the front surface of the insulating material layer 16a, and faces the capacitor conductors 32a and 32b. The capacitors C1 to C3 are defined by the above ground conductor 30a and capacitor conductors 32a to 32c.

In addition, in the electronic component 10b, a ground conductor 30b is a rectangular or substantially rectangular conductor provided on the front surface of the insulating material layer 16p, and is connected to the external electrode 14f via a via-hole conductor b42.

In the electronic component 10b configured as described above, preferably, the external electrode 14a is used as an input port, the external electrode 14b is used as a main output port, the external electrode 14c is used as a monitor output port, the external electrode 14d is used as a 50-Ω terminal port, and the external electrodes 14e and 14f are used as ground ports, for example.

In the electronic component 10b having the above configuration, the direction identification mark MK can be easily formed similarly to the electronic component 10a.

In addition, in the electronic component 10b, since the low-pass filter is provided on the main line ML, the properties of the main line ML and the sub-line SL are different from each other. Thus, it is necessary to accurately identify the direction of the electronic component 10b. Therefore, it is particularly preferred that the direction identification mark MK is provided in the electronic component 10b.

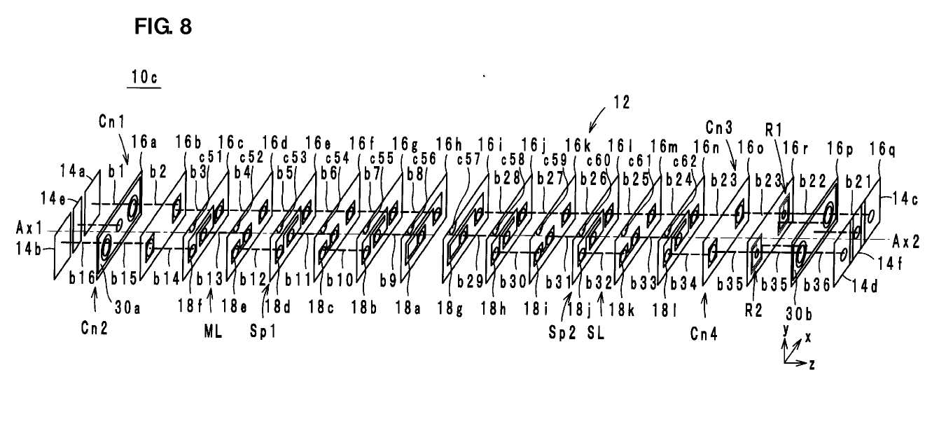

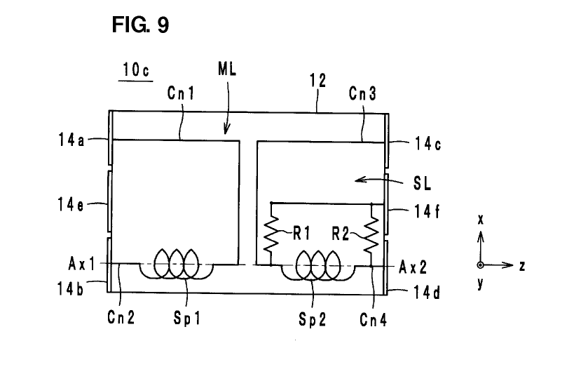

Hereinafter, the electronic component 10c according to a second modification of a preferred embodiment of the present invention will be described with reference to the drawings. FIG. 8 is an exploded perspective view of the electronic component 10c according to the second modification. FIG. 9 is a diagram schematically illustrating the electronic component 10c according to the second modification. It is noted that for an external perspective view of the electronic component 10c, FIG. 5 is used.

In the electronic component 10c, as shown in Figs. and 9, resistors R1 and R2 are provided within the laminate 12, in addition to the main line ML and the sub-line SL.

The resistor R1 is connected between the end of the spiral portion Sp2 on the negative direction side in the z-axis direction and the external electrodes 14e and 14f, and preferably has a spiral shape, for example. The resistor R2 is connected between the end of the spiral portion Sp2 on the positive direction side in the z-axis direction and the external electrodes 14e and 14f, and preferably has a spiral shape, for example. The resistors R1 and R2 preferably have line widths less than that of the signal line 18. The resistors R1 and R2 are formed, for example, by applying a resistive paste including a high-resistance material by screen printing.

In the electronic component 10c configured as described above, preferably, the external electrode 14a is used as an input port, the external electrode 14b is used as a main output port, the external electrode 14c is used as a monitor output port, the external electrode 14d is used as a 50-Ω terminal port, and the external electrodes 14e and 14f are used as ground ports, for example.

In the electronic component 10c having the above configuration, the direction identification mark MK can be easily formed similarly to the electronic component 10a.

In addition, in the electronic component 10c, since the resistors R1 and R2 are provided on the sub-line SL, the properties of the main line ML and the sub-line SL are different from each other. Thus, it is necessary to accurately identify the direction of the electronic component 10c. Therefore, it is particularly preferred that the direction identification mark MK is provided in the electronic component 10c.

The electronic components 10a to 10c according to the preferred embodiment described above are not limited to the described configurations, and can be modified within the scope of the present invention.

It is noted that the direction identification mark MK is preferably defined by the via-hole conductor portions c51 to c62 but may be composed of a via hole filled portion made of a material other than a conductor. However, in this case, the via hole filled portion is preferably formed by filling a via hole with a material different from that of the insulating material layer 16. In addition, so as to improve the adhesion between the via hole filled portion and the insulating material layer 16, the via hole filled portion is preferably formed by filling a via hole with a dielectric material different from that of the insulating material layer 16.

In addition, in the electronic components 10a to 10c, the connection portions Cn1 to Cn4 are included in the laminate 12 and are not exposed from the laminate 12, but may be exposed from the laminate 12. In other words, the connection portions Cn1 to Cn4 may be exposed from the upper surface or the side surfaces on both ends in the x-axis direction. By doing so, a region in which a conductor can be formed in the insulating material layer 16 is expanded, and thus, the flexibility in designing the electronic components 10a to 10c is increased.

As described above, preferred embodiments of the present invention are useful for an electronic component and a method for manufacturing the same, and in particular, are outstanding in that a direction identification mark can be easily formed.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An electronic component comprising:
a laminate including a plurality of insulating material layers that are laminated on one another and a mounting surface parallel or substantially parallel to a lamination direction;
a circuit element provided in the laminate; and
a direction identification mark defined by a via hole filled portion including a material different from that of the insulating material layers, filled into a via hole provided in the insulating material layers and being exposed from an upper surface of the laminate which is parallel or substantially parallel to the mounting surface.

2. The electronic component according to claim 1, wherein the material of the via hole filled portion is the same as a conductor material defining the circuit element.

3. The electronic component according to claim 1, wherein
the insulating material layers are made of a dielectric material; and
the via hole filled portion is made of a dielectric material different from the dielectric material of the insulating material layers.

4. The electronic component according to claim 1, wherein the circuit element includes a directional coupler including a main line and a sub-line which is electromagnetically coupled to the main line.

5. The electronic component according to claim 4, wherein the main line includes a spiral portion disposed in the laminate.

6. The electronic component according to claim 5, wherein the spiral portion of the main line includes spiral conductors disposed on the insulating material layers and via holes extending through the insulating layers and connecting respective ones of the spiral conductors.

7. The electronic component according to claim 4, wherein the sub-line line includes a spiral portion disposed in the laminate.

8. The electronic component according to claim 7, wherein the spiral portion of the sub-line includes spiral conductors disposed on the insulating material layers and via holes extending through the insulating layers and connecting respective ones of the spiral conductors.

9. The electronic component according to claim 1, further comprising external electrodes disposed on at least one surface of the laminate extending perpendicular or substantially perpendicular to the mounting surface, the external electrodes being connected to the circuit element.

10. The electronic component according to claim 4, wherein the circuit element further includes at least one of a capacitor and a resistor.

11. A method for manufacturing the electronic component according to claim 1, the method comprising:
a first step of preparing a mother laminate in which a via hole is filled with a material different from that of the insulating material layers to provide a via hole filled region; and
a second step of cutting the mother laminate to obtain the laminate; wherein
in the second step, the via hole filled region is divided to produce the via hole filled portion.

12. The method for manufacturing the electronic component according to claim 11, wherein the material filled in the via hole filled region is the same as a conductor material defining the circuit element.

13. The method for manufacturing the electronic component according to claim 11, wherein
the insulating material layers are made of a dielectric material; and
the via hole filled portion is made of a dielectric material different from the dielectric material of the insulating material layers.

14. The method for manufacturing the electronic component according to claim 11, wherein the circuit element is a directional coupler including a main line and a sub-line which is electromagnetically coupled to the main line.

15. The method for manufacturing the electronic component according to claim 14, wherein the main line includes a spiral portion disposed in the laminate.

16. The method for manufacturing the electronic component according to claim 15, wherein the spiral portion of the main line includes spiral conductors disposed on the insulating material layers and via holes extending through the insulating layers and connecting respective ones of the spiral conductors.

17. The method for manufacturing the electronic component according to claim 14, wherein the sub-line line includes a spiral portion disposed in the laminate.

18. The method for manufacturing the electronic component according to claim 17, wherein the spiral portion of the sub-line includes spiral conductors disposed on the insulating material layers and via holes extending through the insulating layers and connecting respective ones of the spiral conductors.

19. The method for manufacturing the electronic component according to claim 11, further comprising a third step of forming external electrodes on at least one surface of the laminate extending perpendicular or substantially perpendicular to the mounting surface and electrically connecting the external electrodes to the circuit element.
